(19) United States
(12) Patent Application Publication
(10) Pub. No.: US 2014/0291011 A1
(43) Pub. Date: Oct. 2, 2014

(54) ELECTRONIC DEVICE AND METHOD FOR FABRICATING THE SAME

(71) Applicant: NIHON DEMPA KOGYO CO., LTD., Tokyo (JP)

(72) Inventors: MASAHIRO YOSHIMATSU, SAITAMA (JP); RYOICHI ICHIKAWA, SAITAMA (JP); YASUSHI YAMAMOTO, SAITAMA (JP)

(73) Assignee: NIHON DEMPA KOGYO CO., LTD., Tokyo (JP)

(21) Appl. No.: 14/226,827

(22) Filed: Mar. 27, 2014

(30) Foreign Application Priority Data
Mar. 29, 2013 (JP) 2013-072625

(51) Int. Cl. H05K 5/06

(52) U.S. Cl. CPC H05K 5/065
USPC 174/521; 156/60; 156/280; 156/252

(57) ABSTRACT

An electronic device includes a substrate and a lid bonded on the substrate with a resin layer to seal an inside of the lid. The resin layer is formed at a part of the substrate to which the lid is mounted. A part where the lid is bonded on the substrate with resin layer forms a sealing portion. A glass layer is formed so as to cover the sealing portion.

### CROSS REFERENCE TO RELATED APPLICATIONS

This application claims the priority benefit of Japan application serial no. 2013-072625, filed on Mar. 29, 2013. The entirety of the above-mentioned patent application is hereby incorporated by reference herein and made a part of this specification.

### TECHNICAL FIELD

This disclosure relates to an electronic device and a method for fabricating the electronic device. In particular, this disclosure relates to an electronic device that can improve adhesiveness between a lid and a sealing material (such as a resin) and a method for fabricating the electronic device.

### DESCRIPTION OF THE RELATED ART

### Related Art

As a conventional electronic device, there is a crystal unit for surface mounting or a similar unit. A conventional crystal unit will be described with reference to FIG. 6. FIG. 6 is a cross-sectional explanatory view of a conventional crystal unit. In the conventional crystal unit, a metal or a ceramic lid, which is a lid 1, is mounted on a substrate 2 via a resin layer 4 as illustrated in FIG. 6. The substrate 2 is provided with a crystal element 5 secured to a metal electrode 3 with a conductive adhesive 6. The lid 1 is pressed to the substrate 2 to expand the resin layer 4, thus perform a sealing with the resin.

### Configuration Without Fillet: FIG. 7

As long as the resin layer 4 is pressed and expanded with a contact surface of the lid 1 and forced out from the contact surface (a configuration with a fillet), this does not cause a problem. However, as illustrated in FIG. 7, if the resin layer 4 is not expanded (a configuration without a fillet), water vapor is likely to percolate the resin layer 4, and this may deteriorate moisture proof property. FIG. 7 is a cross-sectional explanatory view illustrating a configuration without a fillet.

### Related Technique

As a pertaining prior art, there are Japanese Patent No. 3183065 “METHOD FOR FABRICATING PIEZOELECTRIC COMPONENT” (Murata Manufacturing Co., Ltd.) [Patent Literature 1], Japanese Patent No. 4471015 “ELECTRONIC DEVICE PACKAGE” (Panasonic Corporation) [Patent Literature 2], Japanese Unexamined Patent Application Publication No. 2010-273200 “METHOD FOR MANUFACTURING PIEZOELECTRIC COMPONENT AND PIEZOELECTRIC COMPONENT MANUFACTURED WITH THE SAME” (NIHON DEMPA KOGYO CO., LTD.) [Patent Literature 3], and Japanese Unexamined Patent Application Publication No. 2012-009969 “PIEZOELECTRIC DEVICE AND METHOD OF MANUFACTURING SAME” (NIHON DEMPA KOGYO CO., LTD.) [Patent Literature 4].

In Patent Literature 1, the following description is disclosed. An inner surface side of an opening of a cap made of metal is inclined to an outer surface side. An adhesive is applied over the opening for performing a sealing with resin. In Patent Literature 2, the following description is disclosed. In an electronic device package, an adhesive of resin bonds a first container member and a second container member. A metal film covers the outside of the second container member and the outside of the adhesive.

In Patent Literature 3, the following description is disclosed. For protection of a piezoelectric component, a surface insulating protective layer is formed. As a specific fabrication method, an application of liquid glass (SOG) is described. Patent Literature 4 discloses a piezoelectric device where a low-melting point glass is formed at an outside of an adhesive.

As described above, in the conventional electronic devices, the resin is uncovered at the bonding surface between the lid and the substrate. In particular, for the electronic device without a fillet, the resin is laterally short. This deteriorates the adhesiveness and moisture proof property, causing a problem of variation in quality.

A need thus exists for an electronic device and a method for fabricating the electronic device which are not susceptible to the drawbacks mentioned above.

### SUMMARY

An electronic device according to the disclosure includes a substrate and a lid bonded on the substrate with a resin layer to seal an inside of the lid. The resin layer is formed at a part of the substrate to which the lid is mounted. A part where the lid is bonded on the substrate with resin layer forms a sealing portion. A glass layer is formed so as to cover the sealing portion.

### BRIEF DESCRIPTION OF THE DRAWINGS

The foregoing and additional features and characteristics of this disclosure will become more apparent from the following detailed description considered with reference to the accompanying drawings, wherein:

FIG. 1 is a cross-sectional explanatory view of a first crystal unit.

FIG. 2 is a cross-sectional explanatory view of a second crystal unit.

FIG. 3 is a cross-sectional explanatory view of a third crystal unit.

FIG. 4 is a cross-sectional explanatory view of a fourth crystal unit.

FIG. 5 is a cross-sectional explanatory view of a fifth crystal unit.

FIG. 6 is a cross-sectional explanatory view of a conventional crystal unit.

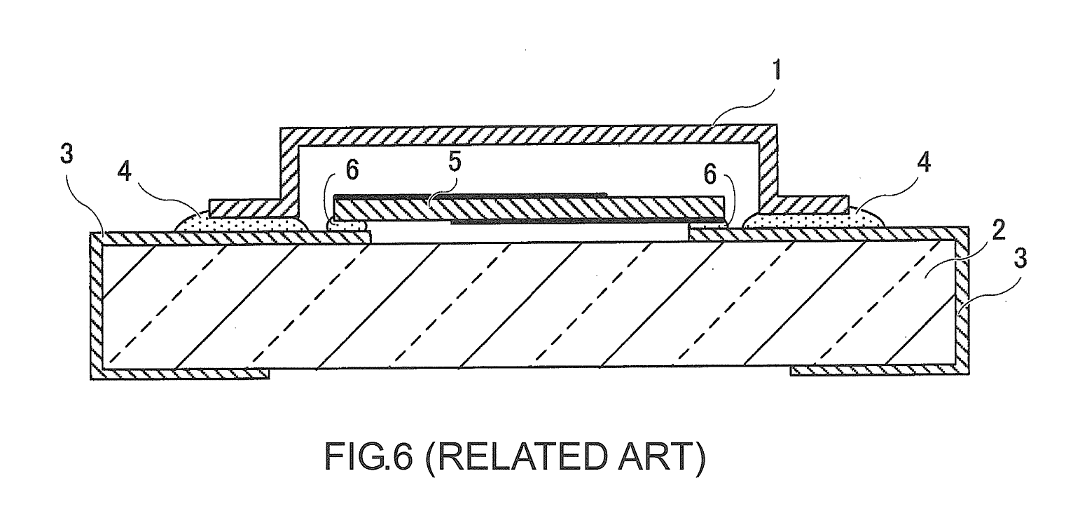

FIG. 7 is a cross-sectional explanatory view illustrating a configuration without a filet.

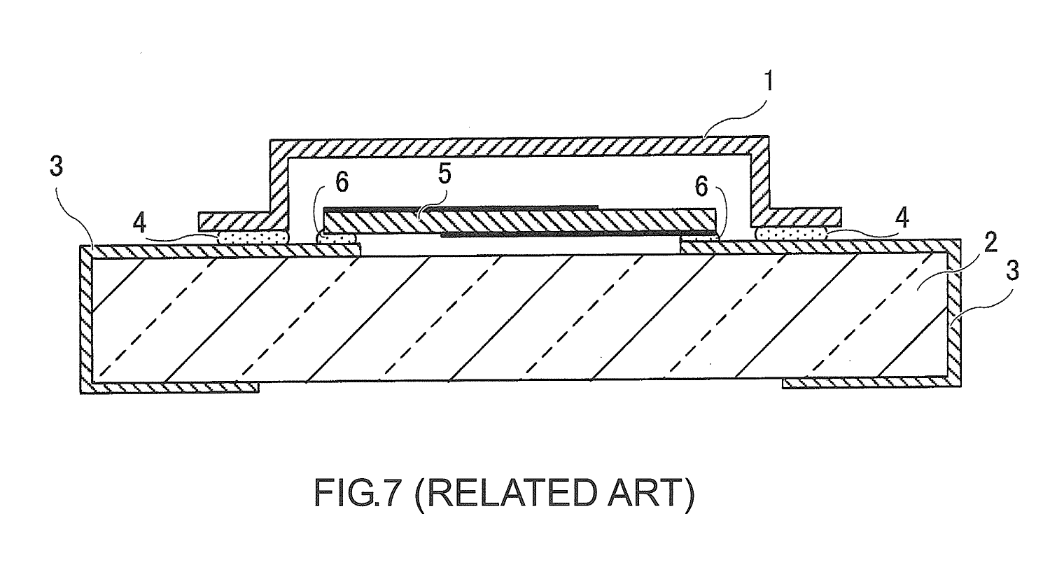

### DETAILED DESCRIPTION

### Outline of Embodiments

Embodiments of this disclosure will be explained with reference to the attached drawings. An electronic device and a method for fabricating the electronic device according to the embodiments of this disclosure are configured as follows. The electronic device includes a substrate, a lid, a sealing portion, and a glass layer. The lid is bonded to the substrate with a resin layer to seal the inside of the lid. A part where the lid is bonded on the substrate with the resin layer forms a sealing portion. The glass layer is disposed so as to cover the sealing portion. These have effects of improving air tightness of the resin, which bonds the substrate to the lid, and improving moisture proof property.

As the electronic device, the following description describes a crystal unit for surface mounting as an example. However, this disclosure is applicable to the electronic device as long as the electronic device has a configuration where a lid is bonded to the substrate with the resin layer and seals the inside of the lid (sealing with resin).

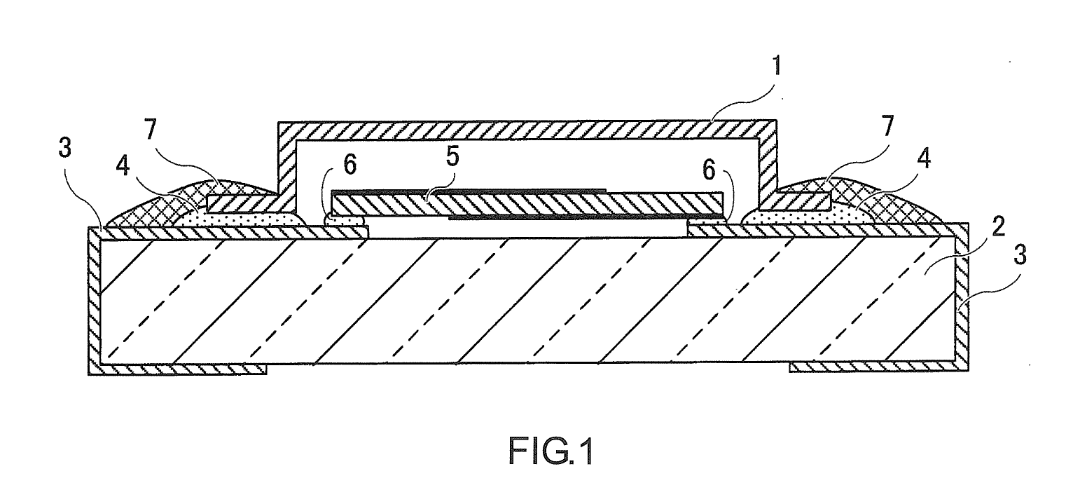

### First Crystal Unit: FIG. 1

A description will be given of a first crystal unit (the first crystal unit) according to the embodiment of this disclosure with reference to FIG. 1. FIG. 1 is a cross-sectional explanatory view of the first crystal unit. As illustrated in FIG. 1, the first crystal unit includes a substrate 2, a metal electrode 3, a crystal element 5, and a lid 1. The metal electrode 3 is formed at the substrate 2 made of ceramic. The crystal element 5 connects to the metal electrode 3 via a conductive adhesive 6. The lid 1 made of metal or ceramic is mounted so as to cover the crystal element 5.

Between the substrate 2 and a mounting surface of the lid 1 with respect to the substrate 2, a resin layer 4 is disposed. The resin layer 4 is pressed by the lid 1 for performing a sealing with resin. As the resin layer 4, for example, an epoxy resin is employed.

Further, the first crystal unit has a feature of forming a glass layer 7 outside the resin layer 4. The glass layer 7 covers not only the outside of the resin layer 4 but also covers a part of the substrate 2 where the resin layer 4 contacts, and a part of the lid 1 where the resin layer 4 contacts. That is, assuming a part where the lid 1 is bonded to the substrate 2 with the resin layer 4 as a sealing portion, the glass layer 7 is formed so as to cover the sealing portion. In particular, a back surface part of the contact surface of the lid 1, which is in contact with the resin layer 4, is covered.

The glass layer 7 is fixed as follows. An insulating film made of a liquid glass (SOG: Spin On Glass) is applied over a peripheral part of the lid 1 which contacts the resin layer 4 by using a dispenser. Then, a heat treatment is performed on the insulating film. Even if a fillet is not formed at the contact surface of the lid 1 in contact with the resin layer 4 (an undercut configuration), the liquid glass of the glass layer 7 also fills a part without a fillet (a part between the lid 1 and the substrate 2 where the resin layer 4 is not formed but a space is formed). Thus, an air tightness of the resin layer 4 formed between the lid 1 and the substrate 2 is improved, and an effect of improving moisture proof property is ensured.

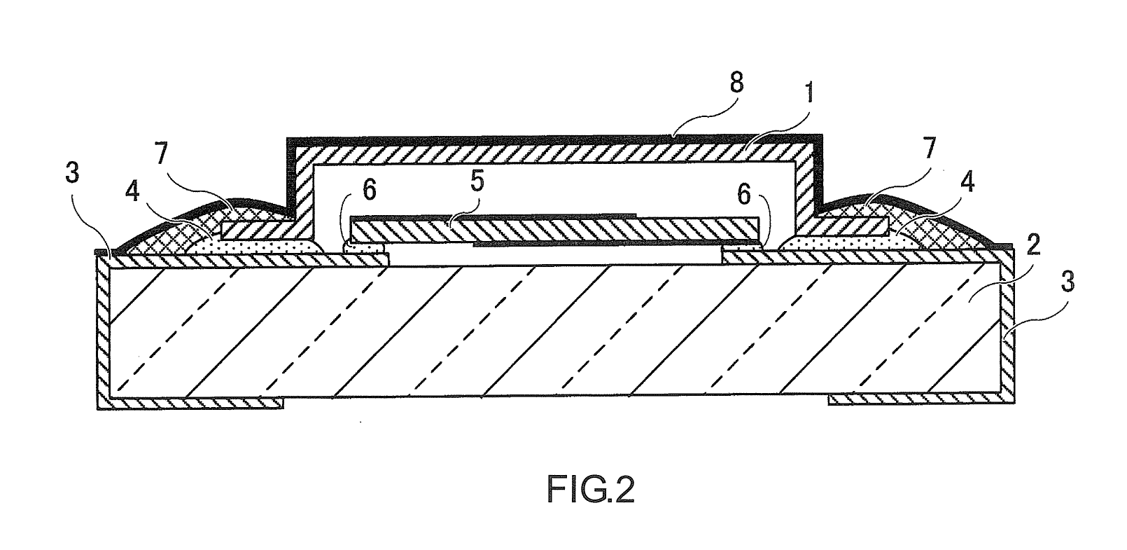

### Second Crystal Unit: FIG. 2

Next, a description will be given of a second crystal unit (the second crystal unit) according to the embodiment of this disclosure with reference to FIG. 2. FIG. 2 is a cross-sectional explanatory view of the second crystal unit. Compared with the configuration of the first crystal unit, the second crystal unit is configured as follows and is illustrated in FIG. 2. In the second crystal unit, a part of the lid 1, the glass layer 7 and a part of the substrate 2, which are exposed in the configuration of the first crystal unit, are further covered by a ceramic layer 8 entirely.

As the ceramic layer 8, for example, a film of silicon nitride (Si₃N₄), which is a nonoxide ceramics, may be employed. Since the first crystal unit is further covered with the ceramic layer 8 to form the second crystal unit, effects of further improving moisture proof property and improving the quality of the product are obtained.

The second crystal unit may include a metal film (a metal layer) instead of the ceramic layer 8. As the metal layer, for example, an aluminum, which is less likely to oxidize, is employed.

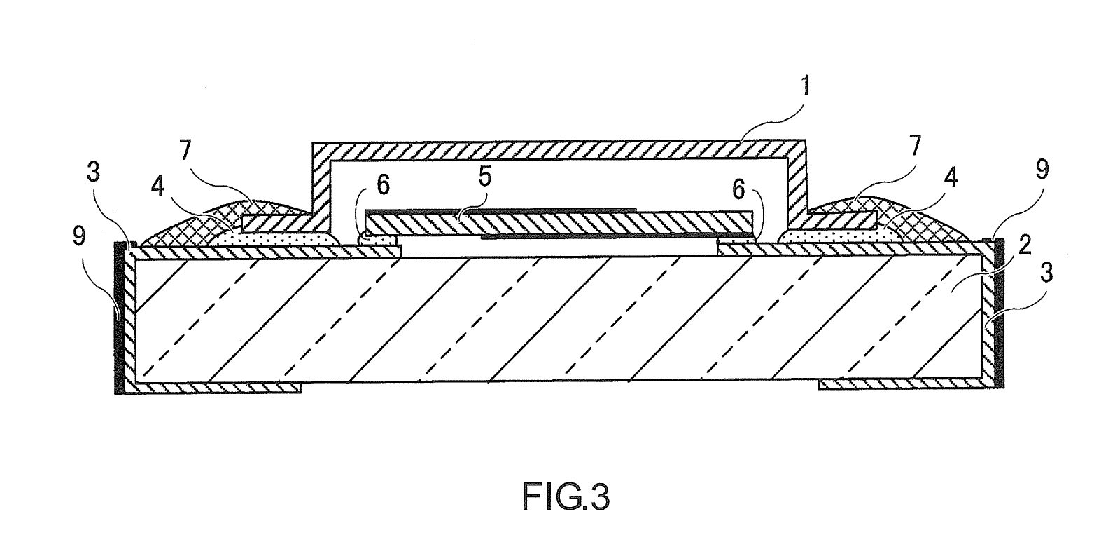

### Third Crystal Unit: FIG. 3

Next, a description will be given of a third crystal unit (the third crystal unit) according to the embodiment of this disclosure with reference to FIG. 3. FIG. 3 is a cross-sectional explanatory view of the third crystal unit. As illustrated in FIG. 3, the third crystal unit is configured as follows. The third crystal unit includes a through hole and a water-repellent layer 9 in the configuration of the first crystal unit. The through hole is formed at the substrate 2. The water-repellent layer 9 is formed in the through hole (the inner wall) and at the opening of the through hole (the top surface opening). The water-repellent layer 9, for example, employs a fluorine-based water repellent agent and is coated and applied with a dispenser.

In the first crystal unit, if a through hole is formed at the substrate 2, the glass layer 7 possibly flows into the through hole. Therefore, since the third crystal unit includes the water-repellent layers 9 at the inner surface and the opening of the through hole, the glass layer 8 is not formed at these parts, thus having an effect of preventing the glass layer 8 from flowing into the through hole.

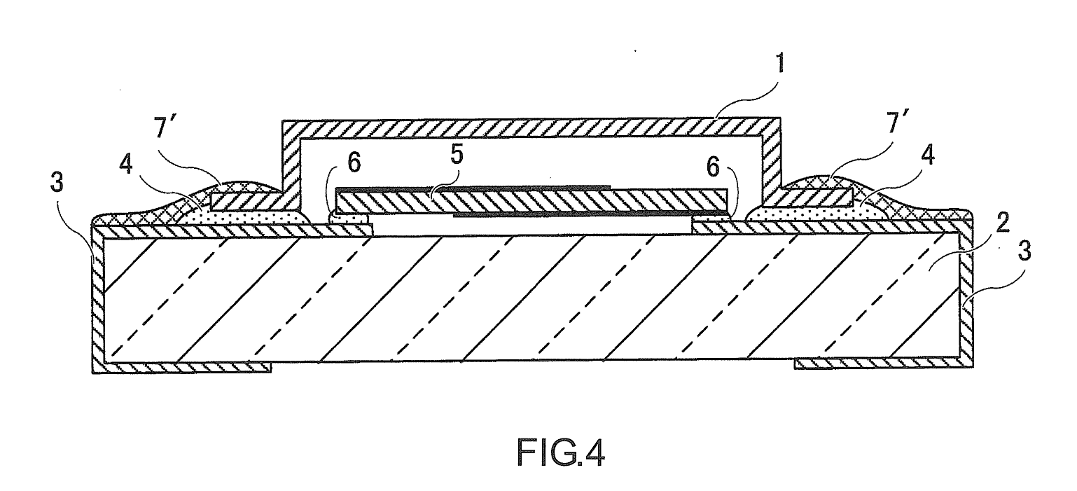

### Fourth Crystal Unit: FIG. 4

Next, a description will be given of a fourth crystal unit (the fourth crystal unit) according to the embodiment of this disclosure with reference to FIG. 4. FIG. 4 is a cross-sectional explanatory view of the fourth crystal unit. As illustrated in FIG. 4, the fourth crystal unit is configured as follows. The fourth crystal unit includes a through hole and a glass layer 7′ in the configuration of the first crystal unit. The through hole is formed at the substrate 2. The glass layer 7′ is formed up to an edge of the opening (the top surface opening) of the through hole.

To form the glass layer 8 up to the edge of the opening of the through hole, water (pure water) is dropped to the through hole, and then the glass layer 7′ is formed so as to cover the sealing portion. This prevents the glass layer 7′ from flowing into the through hole. Thereafter, the through hole is heated to vaporize the water. The above-described method ensures forming the glass layer 7′ up to the very edge of the opening of the through hole.

In the third crystal unit, a water repellent process is performed on the through hole to form the water-repellent layer 9. Accordingly, a capillary action of solder from the back surface of the substrate 2 into the through hole is less likely to occur. However, the fourth crystal unit does not include the water-repellent layer 9. Accordingly, a capillary action of solder into the through hole is likely to occur, enhancing bonding strength of the back surface of the substrate 2 with the metal film. Further, there is an effect of improving moisture proof property at low-price compared with the third crystal unit

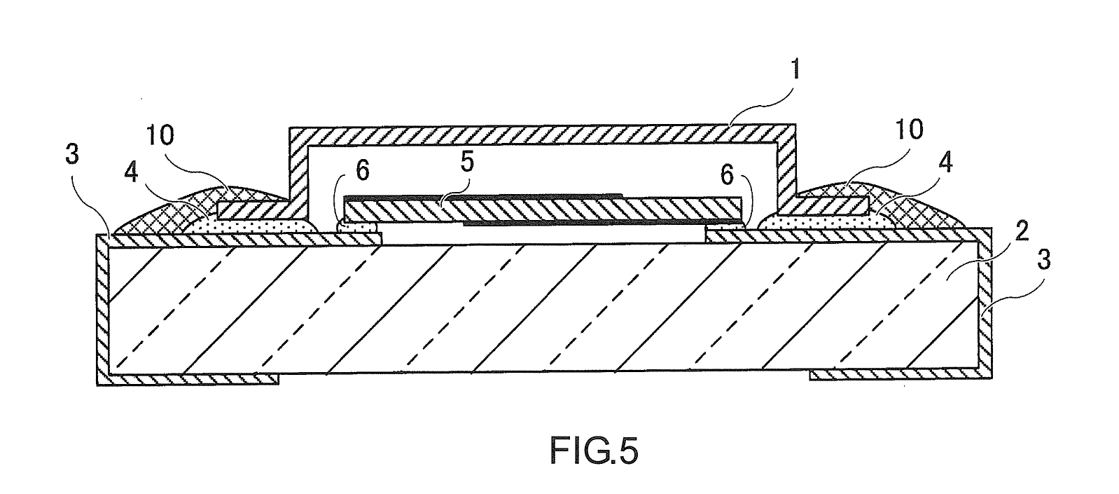

### Fifth Crystal Unit: FIG. 5

Next, a description will be given of a fifth crystal unit (the fifth crystal unit) according to the embodiment of this disclosure with reference to FIG. 5. FIG. 5 is a cross-sectional explanatory view of the fifth crystal unit. As illustrated in FIG. 5, the fifth crystal unit is configured as follows. The fifth crystal unit includes a water-repellent layer 10 in the configuration of the first crystal unit instead of the glass layer 7, so as to cover the sealing portion. The water-repellent layer 10 employs, for example, a fluorine-based water repellent agent and is coated and applied with a dispenser.

The fifth crystal unit features effects of high resistance with respect to thermal expansion and impact. The fifth crystal unit includes the water-repellent layer 10 so as to cover the sealing portion, thus ensuring an effect of improving moisture proof property.

### Effects of Embodiments

According to the first crystal unit, a part where the lid 1 is bonded on the substrate 2 with the resin layer 4 forms a sealing portion. The glass layer 7 is formed so as to cover the sealing portion. Even if a fillet is not formed at a contact surface of the lid 1 in contact with the resin layer 4, the liquid glass of the glass layer 7 is also filled in a part without a fillet. This has effects of improving air tightness of the resin layer 4 formed between the lid 1 and the substrate 2 and improving moisture proof property.

According to the second crystal unit, the entire first crystal unit is covered with the ceramic layer 8. This has an effect of further improving the moisture proof property. According to the second crystal unit, the entire first crystal unit is covered with a metal layer. This has an effect of further improving the moisture proof property.

According to the third crystal unit, the through hole is formed at the substrate of the first crystal unit, and the water-repellent layers 9 are formed at the inner surface and the opening of the through hole. Accordingly, the glass layer 8 is not formed at these part. This has an effect of preventing the liquid glass of the glass layer 8 from flowing into the through hole.

According to the fourth crystal unit, the through hole is formed at the substrate of the first crystal unit, and the glass layer 7′ is formed up to an edge of the opening of the through hole. Accordingly, a capillary action of solder into the through hole is excellent, enhancing bonding strength of the back surface of the substrate 2 with the metal layer. Further, this has an effect of improving the moisture proof property at low-price compared with the third crystal unit, which includes the water-repellent layers 9.

According to the fifth crystal unit, the sealing portion of the first crystal unit is covered with the water-repellent layer 10, the ensuring resistance with respect to thermal expansion and impact. This has an effect of improving the moisture proof property.

This disclosure is preferable for an electronic device that can improve air tightness of the resin, which bonds the substrate to the lid, and improving moisture proof property and a method for fabricating the electronic device.

The disclosure for solving the conventional problems provides an electronic device where a lid is bonded on a substrate with a resin layer and an inside of the lid is sealed. The resin layer is formed at a part of the substrate to which the lid is mounted. A glass layer is formed so as to cover the resin layer, parts where the substrate and the lid are in contact with the resin layer.

The disclosure according to the electronic device features the following. A ceramic layer is formed so as to cover a part of the substrate, the glass layer and a part of the lid which are exposed.

The disclosure according to the electronic device features the following. A metal layer is formed so as to cover a part of the substrate, the glass layer and a part of the lid which are exposed.

The disclosure according to the electronic device features the following. A through hole is formed at the substrate. A water-repellent layer is formed inside the through hole and at an opening of the through hole.

The disclosure according to the electronic device features the following. A through hole is formed at the substrate. A glass layer is formed up to an edge of an opening of the through hole.

The disclosure is an electronic device where a lid is bonded on a substrate with a resin layer and an inside of the lid is sealed. The resin layer is formed at a part of the substrate to which the lid is mounted. A part where the lid is bonded to the substrate with the resin layer forms a sealing portion. A water-repellent layer is formed so as to cover the sealing portion.

The disclosure is a method for fabricating an electronic device that bonds a lid to a substrate with a resin layer. The method for fabricating an electronic device seals an inside of the lid. The method for fabricating an electronic device includes mounting process and forming process. The mounting process mounts the lid to the substrate via the resin layer. The forming process forms a glass layer so as to cover a sealing portion. The sealing portion is a part where the lid is bonded to the substrate with the resin layer.

The disclosure according to the method for fabricating an electronic device features the following. A ceramic layer is formed so as to cover a part of the substrate, the glass layer and a part of the lid which are exposed.

The disclosure according to the method for fabricating an electronic device features the following. A metal layer is formed so as to cover part of the substrate, the glass layer and a part of the lid which are exposed.

The disclosure according to the method for fabricating an electronic device features the following. A through hole is formed at a substrate. A water-repellent layer is formed inside the through hole and an opening of the through hole. The lid is mounted to the substrate via a resin layer.

The disclosure according to the method for fabricating an electronic device features the following. A through hole is formed at a substrate. A glass layer is formed up to an edge of an opening of the through hole.

The disclosure is a method for fabricating an electronic device that bonds a lid to a substrate with a resin layer. The method for fabricating an electronic device seals an inside of the lid. The method for fabricating an electronic device includes mounting process and forming process. The mounting process mounts the lid to the substrate via the resin layer. The forming process forms a water-repellent layer so as to cover a sealing portion. The sealing portion is a part where the lid is bonded to the substrate with the resin layer.

According to the disclosure, an electronic device where a lid is bonded on a substrate with a resin layer and an inside of the lid is sealed is provided. The resin layer is formed at a part of the substrate to which the lid is mounted. A part where the lid is bonded on the substrate with the resin layer forms a sealing portion. A glass layer is formed so as to cover the sealing portion. These have effects of improving air tightness of the resin, which bonds the substrate to the lid, and improving moisture proof property.

According to the embodiment, a method for fabricating an electronic device that bonds a lid to a substrate with a resin layer is provided. The method for fabricating the electronic device seals an inside of the lid. The method for fabricating the electronic device includes mounting process and forming process. The mounting process mounts the lid to the substrate via the resin layer. The forming process forms a glass layer so as to cover a sealing portion. The sealing portion is a part where the lid is bonded to the substrate with the resin layer. These have effects of improving air tightness of the resin, which bonds the substrate to the lid, and improving moisture proof property.

The principles, preferred embodiment and mode of operation of the present invention have been described in the foregoing specification. However, the invention which is intended to be protected is not to be construed as limited to the particular embodiments disclosed. Further, the embodiments described herein are to be regarded as illustrative rather than restrictive. Variations and changes may be made by others, and equivalents employed, without departing from the spirit of the present invention. Accordingly, it is expressly intended that all such variations, changes and equivalents which fall within the spirit and scope of the present invention as defined in the claims, be embraced thereby.

What is claimed is:

1. An electronic device, comprising:
a substrate;
a lid, being bonded on the substrate with a resin layer to seal an inside of the lid, wherein
the resin layer is formed at a part of the substrate to which the lid is mounted, and
a part where the lid is bonded on the substrate with resin layer forms a sealing portion, and a glass layer is formed so as to cover the sealing portion.

2. The electronic device according to claim 1, further comprising:
a ceramic layer, being formed so as to cover a part of the substrate, the glass layer and a part of the lid which are exposed.

3. The electronic device according to claim 1, further comprising:
a metal layer, being formed so as to cover a part of the substrate, the glass layer and a part of the lid which are exposed.

4. The electronic device according to claim 1, further comprising:
a through hole, being formed at the substrate, and
a water-repellent layer, being formed inside the through hole and at an opening of the through hole.

5. The electronic device according to claim 1, further comprising:
a through hole, being formed at the substrate, and
a glass layer, being formed up to an edge of an opening of the through hole.

6. An electronic device, comprising:
a substrate;
a lid, being bonded on the substrate with a resin layer to seal an inside of the lid, wherein
the resin layer is formed at a part of the substrate to which the lid is mounted, and
a part where the lid is bonded to the substrate with the resin layer forms a sealing portion, and a water-repellent layer is formed so as to cover the sealing portion.

7. A method for fabricating the electronic device according to claim 1, comprising:
sealing the inside of the lid by bonding the lid to a substrate with the resin layer and mounting the lid to the substrate via the resin layer; and
forming the glass layer so as to cover the sealing portion, and the sealing portion is the part where the lid is bonded to the substrate with the resin layer.

8. The method for fabricating an electronic device according to claim 7, further comprising:
forming a ceramic layer so as to cover a part of the substrate, the glass layer and a part of the lid which are exposed.

9. The method for fabricating an electronic device according to claim 7, further comprising:
forming a metal layer so as to cover a part of the substrate, the glass layer and a part of the lid which are exposed.

10. The method for fabricating an electronic device according to claim 7, further comprising:
forming a through hole at the substrate;
forming a water-repellent layer inside the through hole and at an opening of the through hole; and
mounting the lid to the substrate via the resin layer.

11. The method for fabricating an electronic device according to claim 7, further comprising:
forming a through hole at the substrate; and
forming the glass layer up to an edge of an opening of the through hole.

12. A method for fabricating the electronic device according to claim 6, comprising:
sealing the inside of the lid by bonding the lid to a substrate with the resin layer and mounting the lid to the substrate via the resin layer; and
forming the water-repellent layer so as to cover the sealing portion, and the sealing portion being the part where the lid is bonded to the substrate with the resin layer.
